(19) United States
(12) Patent Application Publication
(10) Pub. No.: US 2005/0266679 A1
(43) Pub. Date: Dec. 1, 2005

(54) Barrier structure for semiconductor devices

(76) Inventors: Jing-Cheng Lin, HsinChu County (TW); Shau-Lin Shue, Hsinchu (TW)

Correspondence Address: SLATER & MATSIL, L.L.P., 17950 PRESTON ROAD, SUITE 1000, DALLAS, TX, 75252, US

(21) Appl. No.: 10/995,752

(22) Filed: Nov. 23, 2004

Related U.S. Application Data
(60) Provisional application No. 60/574,419, filed on May 26, 2004.

(51) Int. Cl. H01L 21/4763

(52) U.S. Cl. 438/637; 438/643

(57) ABSTRACT

A via having a unique barrier layer structure is provided. In an embodiment, a via is formed by forming a barrier layer in a via. The barrier layer along the bottom of the via is partially or completely removed, and the via is filled with a conductive material. In another embodiment, a first barrier layer is formed along the bottom and sidewalls of the via. Thereafter, the first barrier layer along the bottom of the via is partially or completely removed, and a second barrier layer is formed.

This application claims the benefit of U.S. Provisional Application No. 60/574,419, filed on May 26, 2004, entitled Method For Forming Vias Having Thinner Barrier Layer On Bottom Relative To Sidewall And Devices Formed Thereby, which application is hereby incorporated herein by reference.

### TECHNICAL FIELD

The present invention relates generally to semiconductors and, more particularly, to a semiconductor structure with a barrier layer in a damascene opening and a method for forming such a semiconductor structure in an integrated circuit.

### BACKGROUND

Interconnect structures in ICs (Integrated Circuit) typically include semiconductor structures, such as transistors, capacitors, resistors, and the like, formed on a substrate. One or more conductive layers formed of a metal or metal alloy separated by layers of a dielectric material are formed over the semiconductor structures to interconnect the semiconductor structures and to provide external contacts to the semiconductor structures. A via is formed through the dielectric material to provide electrical connections between conductive layers and to the semiconductor structures.

Barrier layers are frequently used within the vias to prevent or reduce undesirable diffusing of the metal conductor (typically copper or a copper alloy, although other metals or conductors may be employed) into the surrounding dielectric layer (e.g., silicon oxide, FSG, BPSG, a low-k dielectric, or the like). Typically, tantalum and/or tantalum nitride is used as a barrier layer for a copper via/contact structure. Other barrier layers could include titanium, titanium nitride, nitrogen-containing materials, silicon-containing materials or the like.

In conventional processes, a via or contact hole is formed in the dielectric layer, which may comprise a single layer or multiple layers of the same or different materials. The bottom of the via is typically an underlying conductive layer or region, such as an underlying conductor (e.g., copper) of a previously formed conductive layer or an underlying source/drain region or gate electrode of a semiconductor device. The sidewalls of the via are typically formed of the dielectric material in which the hole is formed.

A barrier layer is deposited along the sidewalls and bottom of the via or contact hole. The barrier layer is typically deposited by chemical vapor deposition (CVD), atomic layer deposition (ALD), physical vapor deposition (PVD), or the like. In conventional processes, the deposition process results in a barrier layer in which the thickness of the barrier layer on the bottom of the via is thicker than the barrier layer on the sidewalls, where the barrier layer is needed. Because the barrier layer is typically not as ideal of a conductor as the copper material, however, the barrier layer undesirably increases the resistance of the resulting contact or via. Variation in the bottom thickness results not only in higher contact resistance, but also in more variation from wafer to wafer and lot to lot in the contact resistance, potentially affecting device reliability and yields.

Therefore, there is a need for a barrier layer that prevents or reduces diffusion along the sidewalls as well as reduces the contact resistance between the via and the underlying conductive material.

### SUMMARY OF THE INVENTION

These and other problems are generally solved or circumvented, and technical advantages are generally achieved, by preferred embodiments of the present invention which provides a diffusion barrier layer in a damascene opening.

In accordance with an embodiment of the present invention, a barrier layer for a semiconductor device is provided. The semiconductor device includes a first conductive region, a dielectric layer overlying the first conductive region, and a via formed in the dielectric layer wherein the via has sidewalls and a bottom, the bottom being in electrical contact with at least a portion of the first conductive region. One or more barrier layers are formed along the sidewalls and along the bottom such that a ratio of a first combined thickness of the barrier layers formed along the sidewalls to a second combined thickness of the barrier layers formed along the bottom being greater than about 0.7.

In accordance with another embodiment of the present invention, a method of forming a conductive path is provided. The method includes forming a first conductive region, forming a dielectric over the first conductive region, and forming an opening in the dielectric, wherein the opening has a bottom defined by the first conductive region and a sidewall defined by the dielectric. A first barrier layer is formed along the sidewall and bottom of the opening, and a portion of the barrier layer along the bottom of the opening is removed. Thereafter, the opening is filled with a conductive material. A ratio of a thickness of the barrier layer along the sidewall of the opening to a thickness of the barrier layer along the bottom is greater than about 0.7.

In accordance with yet another embodiment of the present invention, a method of forming a conductive path is provided. The method includes forming a first conductive region and a dielectric layer over a substrate. A via is formed in the dielectric layer, the via having sidewalls and a bottom, and the bottom exposing at least a portion of the first conductive region. A first barrier layer is formed along the sidewalls and the bottom of the via. At least a portion of the first barrier layer along the bottom of the via is removed. A second barrier layer is formed over the first barrier layer. Thereafter, the via is filled with a conductive material. In an embodiment, a ratio of a total thickness of the first barrier layer and the second barrier layer along the sidewalls to a total thickness of the first barrier layer and the second barrier layer along the bottom is greater than about 0.7.

It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a-1e illustrate a first method to form a barrier layer in a damascene structure in accordance with an embodiment of the present invention; and

FIGS. 2a-2c illustrate a second method to form a barrier layer in a damascene structure in accordance with an embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed herein are merely illustrative of specific ways to make and use the invention, and do not limit the scope of the invention.

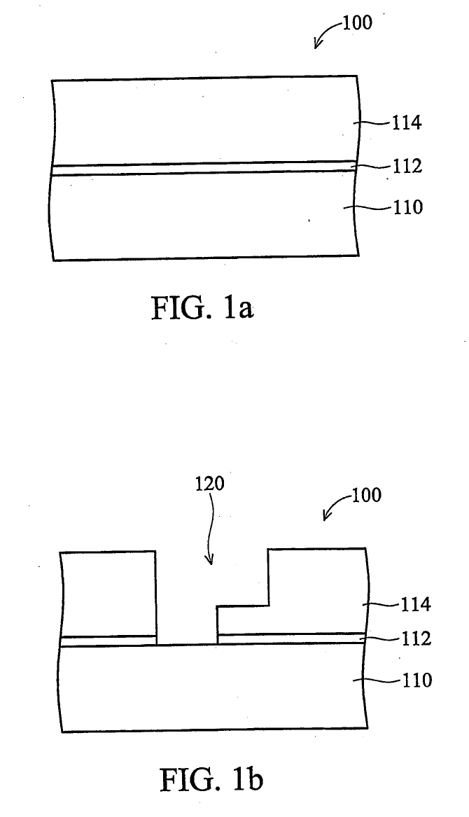

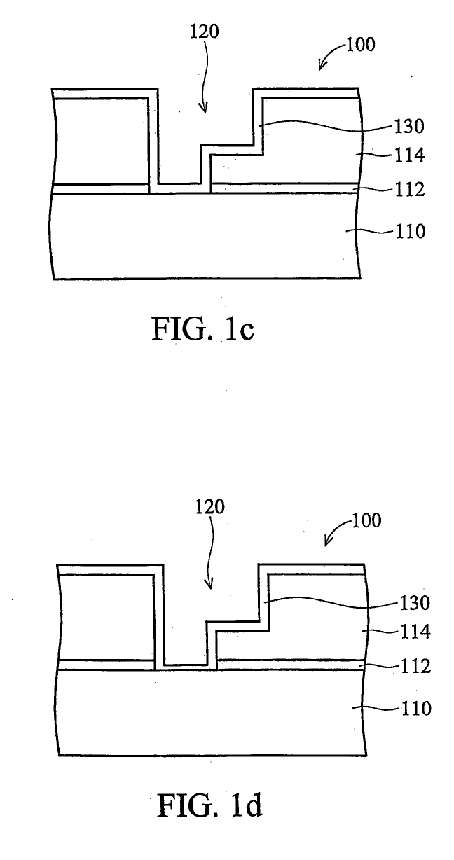

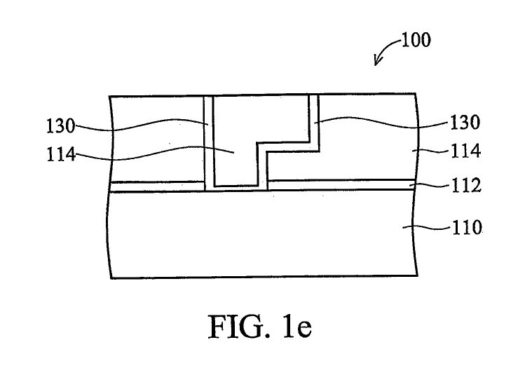

Referring now to FIG. 1a, a substrate 100 is provided having a conductive layer 110, an etch buffer layer 112, and an IMD layer 114. Although it is not shown, the substrate 100 may include circuitry and other structures. For example, the substrate 100 may have formed thereon transistors, capacitors, resistors, and the like. In an embodiment, the conductive layer 110 is metal layer that is in contact with electrical devices or another metal layer.

The conductive layer 110 may be formed of any conductive material, but an embodiment of the present invention has been found to be particularly useful in applications in which the conductive layer 110 is formed of copper. As discussed above, copper provides good conductivity with low resistance. The etch buffer layer 112 provides an etch stop that may be used to selectively etch the IMD layer 114 in a later processing step. In an embodiment, the etch buffer layer 112 may be formed of a dielectric material such as a silicon-containing material, nitrogen-containing material, carbon-containing material, or the like. The IMD layer 114 is preferably formed of a low-K dielectric material, such as FSG, silicon oxide, carbon-containing material, porous-like material, or the like.

It should be noted that the materials selected to form the conductive layer 110, the etch buffer layer 112, and the IMD layer 114 should be selected such that a high-etch selectivity exists between the IMD layer 114 and the etch buffer layer 112 and between the etch buffer layer 112 and the conductive layer 110. In this manner, shapes may be formed in the layers as described below. Accordingly, in an embodiment, the IMD layer 114 comprises silicon oxide (or FSG) formed by deposition techniques such as CVD. In this embodiment, silicon nitride (Si₃N₄) has been found to be a suitable material for the etch buffer layer 112 in which a copper damascene structure is being fabricated.

Referring now to FIG. 1b, a via 120 is formed. It should be noted that the via 120 is illustrated as a dual-damascene structure for illustrative purposes only and may be formed by one or more process steps (e.g., a single damascene process). The via 120 may be formed by photolithography techniques known in the art. Generally, photolithography involves depositing a photoresist material and then irradiating (exposing) and developing it in accordance with a specified pattern to remove a portion of the photoresist material. The remaining photoresist material protects the underlying material from subsequent processing steps, such as etching. The etching process may be a wet or dry, anisotropic or isotropic, etch process, but preferably is an anisotropic dry etch process. After the etching process, the remaining photoresist material may be removed.

In an embodiment in which the IMD layer 114 is formed of FSG, the etch buffer layer 112 is formed of silicon nitride, and the conductive layer 110 is formed of copper, the via 120 may be etched using, for example, a solution of CF₄, C₅F₈, or the like, wherein the etch buffer layer 112 acts as an etch buffer. Therefore, another process utilizing, for example, a solution of CF₄, may be performed to remove the etch buffer layer 112 within the via opening 120, thereby exposing the surface of the conductive layer 110.

It should be noted that a pre-clean process may be performed to remove impurities along the sidewalls of the via 120 and to clean the underlying conductive layer 110. The pre-clean process may be a reactive or a non-reactive pre-clean process. For example, a reactive process may include a plasma process using a hydrogen-containing plasma, and a non-reactive process may include a plasma process using an argon-containing plasma.

FIG. 1c illustrates the substrate 100 of FIG. 1b after a first barrier layer 130 has been formed. The IMD layer 114 is generally formed using a low dielectric constant dielectric layer (low-k dielectric, wherein k is less than about 3.5), which is usually a porous material. The porosity of the IMD layer 114 may induce a diffusion path for the conductive material of the conductive layer 110. To prevent or reduce such diffusion of the conductive material into the IMD layer 114, the first barrier layer 130 may be formed on the sidewall of the via 120.

In an embodiment, the first barrier layer 130 may comprise a silicon-containing layer, carbon-containing layer, nitrogen-containing layer, hydrogen-containing layer, or a metal or a metal compound containing layer, such as tantalum, tantalum nitride, titanium, titanium nitride, titanium zirconium, titanium zirconium nitride, tungsten, tungsten nitride, or alloys, or combinations thereof. The first barrier layer 130 may be formed by a process such as physical vapor deposition (PVD), atomic layer deposition (ALD), spin-on deposition, or other suitable methods. The first barrier layer 130 may be formed at a temperature between about −40° C. and about 400° C. at a pressure between about 0.1 mTorr and about 100 mTorr. The first barrier layer 130 may comprise multiple layers.

Referring now to FIG. 1d, a process is performed to partially remove the first barrier layer 130 along the bottom of the via 120 with an etching process. It is preferred that the ratio of the thickness of the first barrier layer 130 along the sidewalls to the thickness of the first barrier layer 130 along the bottom of the via 120 be greater than about 0.7 and, more preferably, greater than 1.0.

Additionally, it should be noted that in this embodiment, it is preferred that at least a portion of the first barrier layer 130 remain along the bottom of the trench. Leaving at least a portion of the first barrier layer 130 along the bottom of the trench prevents or reduces impurity inter-diffusion from the dielectric, e.g., the IMD layer 114, to the conductive layer.

FIG. 1e illustrates the substrate 100 after the via 120 is filled with a conductive plug 140 and the surface planarized. In an embodiment, the conductive plug 140 comprises a copper material formed by depositing a copper seed layer and forming a copper layer via an electroplating process. The substrate 100 may be planarized by, for example, a chemical-mechanical polishing (CMP) process.

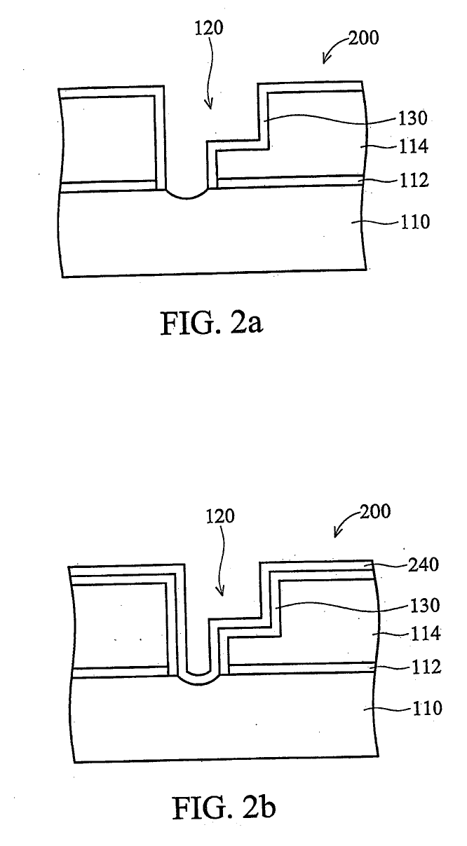

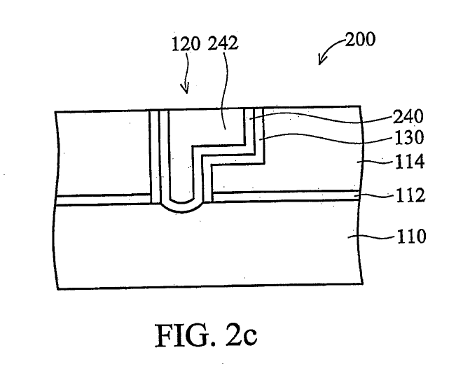

FIGS. 2a-2c illustrate a second embodiment of the present invention. Referring first to FIG. 2a, a substrate 200 is shown that has been formed as discussed above in FIGS. 1a-1c, wherein like reference numerals refer to like elements, and a process has been performed to partially or completely remove the first barrier layer 130 along the bottom of the via.

It should be noted that FIG. 2a also illustrates an optional recess formed in the underlying conductive layer 110 as a result of removing the first barrier layer 130 along the bottom of the via 120. It has been found that a recess formed in the conductive layer 110 may help reduce the amount of resistance between the via 120 and the conductive layer 110. In an embodiment, the depth of the recess portion may be about 0 (no recess) to about 100 nanometers. It should also be noted that the first barrier layer 130 is completely removed along the bottom of the via 120 for illustrative purposes only, and accordingly, a portion of the first barrier layer 130 may remain along the bottom of the via. A redeposited layer (not shown) may be formed along the sidewalls of the via 120 on the first barrier layer 130.

It should be noted, however, that it is preferred that at least a portion of the first barrier layer 130 remain along the bottom of the trench. The first barrier layer 130 on the bottom of the via 120 may be removed and the recess formed in the conductive layer 110 by performing an etching process.

Referring now to FIG. 2b, a second barrier layer 240 is formed. The second barrier layer 240 preferably comprises a conductive material, such as a silicon-containing layer, carbon-containing layer, nitrogen-containing layer, hydrogen-containing layer, or a metal or a metal compound containing layer, such as tantalum, tantalum nitride, titanium, titanium nitride, titanium zirconium, titanium zirconium nitride, tungsten, tungsten nitride, cobalt, nickel, ruthenium, palladium, or alloys, or combinations thereof, but more preferably, relatively pure titanium, tantalum, cobalt, nickel, palladium, or the like. The second barrier layer 240 may be formed by a process such as physical vapor deposition (PVD), chemical vapor deposition (CVD), plasma-enhanced CVD (PECVD), low-pressure CVD (LPCVD), atomic layer deposition (ALD), spin-on deposition, or other suitable methods. The second barrier layer 240 may be formed at a temperature between about −40° C. and about 400° C. at a pressure between about 0.1 mTorr and about 100 mTorr. The second barrier layer 240 may comprise multiple layers.

To achieve a better step coverage on the sidewall and to achieve good resistivity properties along the bottom of the via 120, the thickness of the second barrier layer 240 along the bottom of the via 120 may be less than the total thickness of first barrier layer 130 and the second barrier layer 240 along the sidewall of the vias 120. (Note that the first barrier layer may not run along the bottom of the via.) In an embodiment the ratio of the total thickness of the barrier layers along the sidewalls of the via 120 to the total thickness of the barrier layers along the bottom of the via 120 is greater than 0.7 and, more preferably, greater than 1.0.

The barrier layers on the sidewall may also have different thicknesses to achieve step coverage. The preferred thickness ratio of the first barrier layer 130 to the second barrier layer 240 along the sidewall of the via 120 is about 1:20 to about 20:1. In an embodiment, the first sidewall barrier layer has thickness of about 5 to 300 Å, and the second sidewall barrier layer has a thickness of about 5 to about 300 Å. It has been found that the use of a second barrier layer formed after performing the thinning process to reduce the thickness of the first barrier layer along the bottom of the via reduces or avoids the thinning effect at the corner of the opening.

FIG. 2c illustrates the substrate after the via 120 is filled with a conductive plug 242 and the surface planarized. In an embodiment, the conductive plug 242 comprises a copper material formed by depositing a copper seed layer and forming a copper layer via an electro-plating process. The step may be planarized by, for example, a chemical-mechanical polishing (CMP) process.

Thereafter, standard processes may be used to complete fabrication and packaging of the semiconductor device.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor device comprising:
a first conductive region;
a dielectric layer overlying the first conductive region;
a via formed in the dielectric layer, the via having sidewalls and a bottom, the bottom in contact with at least a portion of the first conductive region;
one or more barrier layers formed along the sidewalls and along the bottom, a ratio of a first combined thickness of the one or more barrier layers formed along the sidewalls to a second combined thickness of the one or more barrier layers formed along the bottom being greater than about 0.7.

2. The semiconductor device of claim 1, further comprising a recess formed in the first conductive region under the via.

3. The semiconductor device of claim 1, wherein one or more of the barrier layers comprise ruthenium.

4. The semiconductor device of claim 1, wherein one or more of the barrier layers comprise tantalum.

5. The semiconductor device of claim 1, wherein the dielectric layer comprises a low-k material.

6. The semiconductor device of claim 1, wherein the barrier layers comprise a first barrier layer formed along the sidewalls and a second barrier layer formed along the sidewalls and the bottom.

7. The semiconductor device of claim 1, wherein the barrier layers comprise a first barrier layer and a second barrier layer, the first barrier layer not being located along the bottom of the via.

8. The semiconductor device of claim 1, wherein the barrier layer is substantially the same thickness on the sidewall as on the bottom.

9. The semiconductor device of claim 1, wherein the barrier layers comprise a silicon-containing layer, a carbon-containing layer, a nitrogen-containing layer, a hydrogen-containing layer, a metal or a metal compound containing layer, or combinations thereof.

10. The semiconductor device of claim 9, wherein the metal includes titanium, cobalt, nickel, or palladium.

11. A method of forming a conductive path comprising:
forming a first conductive region;
forming a dielectric over the first conductive region;
forming an opening in the dielectric, the opening having a bottom defined by the first conductive region and a sidewall defined by the dielectric;
forming a first barrier layer along the sidewall and bottom of the opening;
removing a portion of the first barrier layer along the bottom of the opening such that a thin layer of the first barrier layer remains; and
forming a conductor within the opening,
wherein a ratio of a combined thickness of the first barrier layer along the sidewall of the opening to a thickness of the first barrier layer along the bottom is greater than about 0.7.

12. The method of claim 11, further comprising forming a second barrier layer on the first barrier layer after the step of removing a portion of the first barrier layer along the bottom of the opening.

13. The method of claim 11, wherein the first barrier layer comprises a plurality of barrier layers.

14. The method of claim 11, wherein forming a conductor comprises forming a seed layer.

15. The method of claim 11, wherein the step of removing a portion of the first barrier layer comprises an ion etch step.

16. The method of claim 11, wherein the first barrier layer comprises cobalt, nickel, palladium, or ruthenium.

17. A method of forming a conductive path, the method comprising:
forming a first conductive region on a substrate;
forming a dielectric layer over the first conductive region;
forming an opening having a via and a trench in the dielectric layer, the via and trench having sidewalls and a bottom, the bottom of the via exposing at least a portion of the first conductive region;
forming a first barrier layer along the sidewalls and the bottom of the via;
removing at least a portion of the first barrier layer along the bottom of the via;
forming a second barrier layer along the sidewalls and the bottom of the via on the first barrier layer and the bottom of the via; and
forming a conductive material in the via, the conductive material filling the via,
wherein a ratio of a total thickness of the first barrier layer and the second barrier layer along the sidewalls to a total thickness of the first barrier layer and the second barrier layer along the bottom is greater than 0.7.

18. The method of claim 17, wherein the removing includes forming a recess in the first conductive region.

19. The method of claim 17, wherein forming the conductive material comprises forming a seed layer.

20. The method of claim 17, wherein the step of removing a portion of the first barrier layer comprises an ion etch step.

21. A method of forming a conductive path comprising:
forming a first conductive region;
forming a dielectric over the first conductive region;
forming an opening in the dielectric, the opening comprising a trench and a via; a bottom of the via being defined by the first conductive region;
forming a first barrier layer along exposed surfaces of the opening;
removing a portion of the first barrier layer along the bottom of the via such that at least a portion of the first barrier layer remains along the bottom of the trench;
forming a second barrier layer over the first barrier layer; and
forming a conductor within the opening,
wherein a ratio of combined thickness of the first barrier layer and second barrier layer along a sidewall of the opening to a thickness of a combined thickness of the first barrier layer and second barrier layer along the bottom is greater than about 0.7.

22. The method of claim 21, wherein the first barrier layer comprises a plurality of barrier layers.

23. The method of claim 21, wherein forming a conductor comprises forming a seed layer.

24. The method of claim 21, wherein the step of removing a portion of the first barrier layer comprises an ion etch step.

25. A semiconductor device comprising:
a first conductive region;
a dielectric layer overlying the first conductive region;
an opening formed in the dielectric layer, the opening having a via and a trench, the via having sidewalls and a bottom, the bottom in contact with at least a portion of the first conductive region;
a first barrier layer formed over the opening, at least a portion of the first barrier layer being formed along a bottom surface of the trench; and
a second barrier layer formed over the first barrier layer, wherein a ratio of a combined thickness of the barrier layers formed along the sidewalls to a second combined thickness of the barrier layers formed along the bottom being greater than about 0.7.

26. The semiconductor device of claim 25, further comprising a recess formed in the first conductive region under the via.

27. The semiconductor device of claim 25, wherein one or more of the barrier layers comprise ruthenium.

28. The semiconductor device of claim 25, wherein one or more of the first barrier layer and the second barrier layer comprises tantalum.

29. The semiconductor device of claim 25, wherein the dielectric layer comprises a low-k material.

30. The semiconductor device of claim 25, wherein the first barrier layer is not located along the bottom of the via.

31. The semiconductor device of claim 25, wherein the first and second barrier layers comprise a silicon-containing layer, a carbon-containing layer, a nitrogen-containing layer, a hydrogen-containing layer, a metal or a metal compound containing layer, titanium, cobalt, nickel, palladium, or combinations thereof.
